(19) United States
(12) Patent Application Publication
(10) Pub. No.: US 2024/0047958 A1
(43) Pub. Date: Feb. 8, 2024

(54) CIRCUIT BREAKER DEVICE AND METHOD

(71) Applicant: Siemens Aktiengesellschaft, München (DE)

(72) Inventors: Marvin Tannhäuser, Hausen (DE); Dominic Malane, Eichstätt (DE); Fabian Döbler, Theilenhofen (DE)

(21) Appl. No.: 18/258,606

(22) PCT Filed: Dec. 21, 2021
(86) PCT No.: PCT/EP2021/087088

§ 371 Date: Jun. 21, 2023

(30) Foreign Application Priority Data
Dec. 21, 2020 (DE) 10 2020 216 416.9
Dec. 20, 2021 (EP) 21216116.0

(51) Int. Cl. H02H 3/05; H02H 3/38; H02H 5/04

(52) U.S. Cl. CPC H02H 3/05; H02H 3/38; H02H 5/041

(57) ABSTRACT

A circuit breaker device has a mechanical break contact unit connected in series with an electronic interruption unit. The mechanical break contact unit is switched by breaking contacts to prevent current from flowing or by closing the contacts to allow current to flow in the low-voltage circuit. The electronic interruption unit is switched by semiconductor-based switching elements into a high-impedance state of the switching elements to prevent current from flowing or into a low-impedance state of the switching elements to allow current to flow in the low-voltage circuit. An amplitude of the current in the low-voltage circuit is ascertained such that analog momentary current values are provided which are compared with a current threshold value by an analog comparator, and if the threshold value is exceeded, prevention of current flowing in the low-voltage circuit is initiated, in particular by switching the electronic interruption unit into the high-impedance state.

The invention relates to the technical field of a circuit breaker device for a low-voltage circuit having an electronic interruption unit and to a method for a circuit breaker device for a low-voltage circuit having an electronic interruption unit.

Low voltage is understood to mean voltages of up to 1000 volts AC or up to 1500 volts DC. Low voltage is understood in particular to mean voltages that are greater than extra-low voltage, with values of 50 volts AC or 120 volts DC.

A low-voltage circuit or grid or installation is understood to mean circuits with nominal currents or rated currents of up to 125 amperes, more specifically up to 63 amperes. A low-voltage circuit is understood to mean in particular circuits with nominal currents or rated currents of up to 50 amperes, 40 amperes, 32 amperes, 25 amperes, 16 amperes or 10 amperes. Said current values are understood to mean in particular nominal, rated or/and shutdown currents, that is to say the maximum current that is normally carried through the circuit or in the case of which the electrical circuit is usually interrupted, for example by a protection device, such as a circuit breaker device, miniature circuit breaker or power circuit breaker.

Miniature circuit breakers are overcurrent protection devices that have long been known and that are used in low-voltage circuits in electrical installation engineering. They protect lines against damage caused by heating due to excessively high current and/or a short circuit. A miniature circuit breaker may automatically shut down the circuit in the event of an overload and/or short circuit. A miniature circuit breaker is not a safety element that resets automatically.

In contrast to miniature circuit breakers, power circuit breakers are intended for currents greater than 125 A, in some cases also starting from 63 amperes. Miniature circuit breakers therefore have a simpler and more delicate design. Miniature circuit breakers usually have a fastening option for fastening to a so-called top-hat rail (carrier rail, DIN rail, TH35).

Miniature circuit breakers have an electromechanical design. In a housing, they have a mechanical switching contact or operating current tripping device for interrupting (tripping) the electric current. A bimetal protection element or bimetal element is usually used for tripping (interruption) in the event of a sustained overcurrent (overcurrent protection), respectively in the event of a thermal overload (overload protection). An electromagnetic tripping device with a coil is used for brief tripping in the event of an overcurrent limit value being exceeded or in the event of a short circuit (short circuit protection). One or more arc extinguishing chambers or arc extinguishing devices are provided. Connection elements for conductors of the electrical circuit to be protected are also provided.

Circuit breaker devices having an electronic interruption unit are relatively recent developments. They have a semiconductor-based electronic interruption unit. In other words, the electric current flow in the low-voltage circuit is guided via semiconductor components or semiconductor switches that are able to interrupt the electric current flow or are able to be switched to the on state. Circuit breaker devices having an electronic interruption unit often also have a mechanical isolating contact system, in particular with isolator properties in accordance with the applicable standards for low-voltage circuits, wherein the contacts of the mechanical isolating contact system are connected in series with the electronic interruption unit, that is to say the current of the low-voltage circuit to be protected is guided both through the mechanical isolating contact system and through the electronic interruption unit.

In the case of semiconductor-based circuit breaker devices or protection devices, or solid-state circuit breakers, SSCB for short, the switching energy does not, like in the case of a mechanical switching device, have to be converted into an arc, but rather converted into heat by way of an additional circuit, the energy absorber. The shutdown energy in this case comprises the energy stored in the circuit, that is to say in the grid impedances, line impedances or load impedances (consumer impedances). To unload the energy absorber, the current flowing at the time of shutdown has to be as low as possible. This also applies to the case of a short circuit. In this case, the current rises very quickly. Quickly recognizing a short circuit makes it possible to recognize a short circuit early and to avoid an excessively high short-circuit current. The semiconductor-based circuit breaker device interrupts the circuit almost without a delay, within μs, as part of a shutdown process. No high currents occur and the loading of the energy absorber of a semiconductor-based circuit breaker device is reduced. Known short-circuit recognitions or shutdown criteria are usually based on ascertaining and evaluating the current actual value.

The present invention relates to low-voltage AC circuits having an AC voltage, usually having a time-dependent sinusoidal AC voltage of frequency f, typically 50 or 60 hertz (Hz). The temporal dependency of the instantaneous voltage value u(t) of the AC voltage is described by the equation:

u(t)=U*sin(2π*f*t),

wherein:
u(t)=instantaneous voltage value at the time t
U=amplitude (maximum value) of the voltage

A harmonic AC voltage may be represented by the rotation of a vector the length of which corresponds to the amplitude (U) of the voltage. The instantaneous deviation is in this case the projection of the vector onto a coordinate system. An oscillation period corresponds to a full revolution of the vector and its full angle is 2π (2pi) or 360°. The angular frequency is the rate of change of the phase angle of this rotating vector. The angular frequency of a harmonic oscillation is always 2π times its frequency, that is to say:

ω=2π*f=2π/T=angular frequency of the AC voltage

(T=period duration of the oscillation).

It is often preferred to give the angular frequency (ω) rather than the frequency (f), since many formulae in oscillation theory are able to be represented more compactly using the angular frequency due to the occurrence of trigonometric functions the period of which is by definition 2π:

u(t)=U*sin(ωt)

In the case of non-temporally constant angular frequencies, the term instantaneous angular frequency is also used.

In the case of a sinusoidal, in particular temporally constant, AC voltage, the time-dependent value formed from the angular velocity ω and time t corresponds to the time-dependent angle φ(t), which is also referred to as phase angle φ(t). In other words, the phase angle φ(t) periodically runs through the range 0 . . . 2π or 0° . . . 360°. In other words, the phase angle periodically adopts a value between 0 and 2π or 0° and 360° (φ=n*(0 . . . 2π) or φ=n*(0° . . . 360°, owing to periodicity; for short: φ=0 . . . 2π or φ=0° . . . 360°).

Instantaneous voltage value u(t) is therefore understood to mean the instantaneous value of the voltage at the time t, that is to say, in the case of a sinusoidal (periodic) AC voltage, the value of the voltage at the phase angle φ (φ=0 . . . 2π or φ=0° . . . 360°, of the respective period).

The object of the present invention is to improve a circuit breaker device of the type mentioned at the outset, in particular to give a possibility, in the event of an occurring short circuit or overcurrent, that is to say in the event of at least one current threshold value being exceeded, for the electronic interruption unit to quickly avoid an electric current flow.

This object is achieved by a circuit breaker device having the features of patent claim 1 or a method as claimed in patent claim 12.

According to the invention, provision is made for an (electronic) circuit breaker device for protecting an electrical low-voltage circuit, in particular low-voltage AC circuit, having:
a housing, having first, in particular grid-side, and second, in particular load-side, connections for conductors of the low-voltage circuit,
a mechanical isolating contact unit that is connected in series with an electronic interruption unit, wherein in particular the mechanical isolating contact unit is assigned to the (second) load-side connections and the electronic interruption unit is assigned to the (first) grid-side connections,
wherein the mechanical isolating contact unit is able to be switched by opening contacts so as to avoid a current flow or closing the contacts to allow a current flow in the low-voltage circuit,
wherein the electronic interruption unit is able to be switched by semiconductor-based switching elements to a high-resistance state of the switching elements so as to avoid a current flow or a low-resistance state of the switching elements so as to allow a current flow in the low-voltage circuit,
a current sensor unit for ascertaining the level of the current of the low-voltage circuit, such that (analog) instantaneous current values are present,
in particular in one embodiment, a voltage sensor unit for ascertaining the level of the voltage of the low-voltage circuit such that (analog) instantaneous voltage values are present,
a control unit that is connected to the current sensor unit (the voltage sensor unit), the mechanical isolating contact unit and the electronic interruption unit,
wherein the control unit is designed such that provision is made for a microprocessor-controlled digital second subunit that provides at least one digital first current threshold value,
wherein provision is made for an analog first subunit, having an analog first comparator that is connected to the current sensor unit, on the one hand, and that is connected to the microprocessor-controlled digital second subunit, on the other hand, wherein provision is made for a first digital-to-analog converter that converts the at least one digital first current threshold value into at least one analog first current threshold value,
wherein the analog first comparator (continuously) compares the analog instantaneous current value with the at least one analog first current threshold value and, in the event of an exceedance, outputs a signal for avoiding the current flow in the low-voltage circuit at its output.

In particular, in the event of the analog instantaneous current value exceeding the at least one analog first current threshold value, avoidance of a current flow in the low-voltage circuit is initiated. In particular, more specifically, the electronic interruption unit (EU) brings about avoidance of the current flow by switching to the high-resistance state.

This has the particular advantage that, by virtue of the architecture according to the invention, the circuit breaker device, in the event of an occurring overcurrent or short circuit, is able to quickly avoid this, that is to say shut it down, in particular by way of the electronic interruption unit. The design of the control unit with an analog first subunit and a digital second subunit has the particular advantage that an efficient architecture is present. The first analog subunit is able to perform a very fast comparison between analog instantaneous values and analog threshold values, as a result of which fast short-circuit recognition is possible. The second subunit may perform threshold value provision that is independent thereof and that does not need to be as fast as the recognition. The one or more threshold values may for example be buffer stored in order to be available for a fast comparison. The threshold values do not need to be adapted constantly.

Fast or quickly in this connection means that the semiconductor-based switching elements (for example power semiconductors) are protected against thermal destruction. The shutdown performance of the electronic interruption unit, in particular its semiconductor-based switching elements ((power) semiconductors), is limited by the (present) current or by the (present) temperature of the (power) semiconductor, in particular by the amount of energy provided at high currents, which could lead to thermal overloading. In order to achieve fast shutdown (in particular to guarantee this in the event of at least one current threshold value being exceeded) without oversizing the electronic interruption unit, in particular its semiconductor-based switching elements ((power) semiconductors), the architecture according to the invention is proposed. According to the invention, this thus makes it possible to achieve high efficiency and better economic use with units of a simple design.

Analog values or analog units or comparators are understood to mean articles in analog circuitry or analog signal engineering, such as analog electronic circuits that process value-continuous and time-continuous signals. By way of example, an analog comparator may process analog electrical signals (such as voltages) at input and outputs a discrete signal (0 or 1) at output. An analog unit performs processing steps based on an electrical circuit, and the processing steps are defined based on the electrical circuit.

Digital values or units or components are understood to mean articles in digital engineering and digital signals, in particular integrated circuits or systems such as microcontrollers that process signals in a value-discrete and time-discrete manner, that is to say signals with stepped values (quantization) and with stepped time increments (sampling/discretization). Digital systems, especially with microprocessors, may be programmed by way of firmware.

Advantageous embodiments of the invention are indicated in the dependent claims.

In one advantageous embodiment of the invention, the analog first subunit has an analog first and an analog second comparator that are both connected to the current sensor unit, which provides the analog instantaneous current value for both comparators, on the one hand, and to the microprocessor-controlled digital second subunit, on the other hand,
wherein the microprocessor-controlled digital second subunit provides the at least one digital first current threshold value for the first comparator and at least one digital second current threshold value for the second comparator,
wherein provision is made for a second digital-to-analog converter that converts the at least one digital second current threshold value into at least one analog second current threshold value,
wherein the analog first comparator (continuously) compares the analog instantaneous current value with the at least one analog first current threshold value and,
in the event of an exceedance, outputs a signal for avoiding the current flow in the low-voltage circuit at its output,
wherein the analog second comparator (continuously) compares the analog instantaneous current value with the at least one analog second current threshold value and,
in the event of an undershoot, outputs a signal for avoiding the current flow in the low-voltage circuit at its output.

In particular, in the event of the analog instantaneous current value exceeding the at least one analog first current threshold value, avoidance of a current flow in the low-voltage circuit is initiated and, in the event of the analog instantaneous current value falling below the at least one analog second current threshold value, avoidance of a current flow in the low-voltage circuit is initiated, in particular wherein, in both cases, the electronic interruption unit (EU) switches to the high-resistance state. This has the particular advantage of enabling an advantageous solution in particular for low-voltage AC circuits and of enabling recognition with regard to the exceedance of current threshold values both in the positive and in the negative half-cycle of the AC voltage, so as to achieve fast recognition of the exceedance of current threshold values and fast shutdown.

The analog first subunit and the digital second subunit are part of the control unit. The analog first subunit and the digital second subunit may be part of a special microcontroller or of a special integrated circuit that has both digital circuit parts and analog circuit parts. The analog first subunit and the digital second subunit may be at least partially integrated in a unit or an integrated circuit or microprocessor (=microcontroller). A subunit is not necessarily understood to mean a physical separation, but rather a logic or programming one (digital subunit programmable, analog subunit not programmable). The analog first subunit is understood to mean the part that operates with or processes analog signals. The digital second subunit is understood to mean the part that has a programmable microprocessor (=microcontroller=controller) that is programmable and contains program code.

In one advantageous embodiment of the invention, provision is made for a temperature sensor unit, connected to the control unit, in particular to the second subunit, for ascertaining the level of at least one temperature in the circuit breaker device, in particular for ascertaining at least one temperature of a unit of the circuit breaker device, in particular at least one temperature of the electronic interruption unit, such that (analog) instantaneous temperature values are present.

This has the particular advantage that in particular the semiconductor-based switching elements are able to be monitored with regard to their temperature and the current threshold values may possibly be adapted.

In one advantageous embodiment of the invention, the circuit breaker device is designed such that in particular the microprocessor-controlled digital second subunit is designed such that the at least one first or/and second current threshold value is computed digitally, in particular that the current threshold value is computed taking into consideration the level of the temperature, the level of the voltage or the level of the instantaneous current value,
in particular that the at least one current threshold value is adapted depending on the level of the temperature or of the voltage or of the current such that, in the case of an increasing temperature or decreasing voltage or increasing current, the at least one current threshold value is reduced and, in the case of a decreasing temperature or increasing voltage or decreasing current, the at least one current threshold value is increased, in particular is increased up to a maximum value of the at least one current threshold value.

This has the particular advantage that the circuit breaker device shuts down quickly (interrupts the current) taking into consideration further parameters, wherein the shutdown threshold is adapted depending on the parameters (voltage, temperature, current) in order to guarantee fast shutdown.

This also has the particular advantage that the processing speed of an analog circuit (typically in the range of a few nanoseconds [ns], for example 5-10 ns) is combined with the flexibility of a digital programmable and intelligent system (for example microprocessor/microcontroller).

The analog comparator operates in a time-continuous manner, that is to say not in a time-discrete manner. It is thus possible to recognize an overcurrent (exceedance of current threshold value) in a very short time. A microprocessor/microcontroller operates as a time-discrete controller, such that the reaction time is limited to the processing cycle, which is typically in the range from 10-100 μs.

This combination makes it possible to maintain the flexibility and adaptability of a digital (instantaneous) current threshold value and at the same time to achieve the high reaction time of the analog circuit. This is possible since the adaptation of the current threshold value does not have to take place in the nanosecond range/ns, and only the comparison thereof with the (present) instantaneous value of the current value should be performed in the ns range, which is possible by virtue of this arrangement/combination.

In one advantageous embodiment of the invention, the circuit breaker device is designed such that the at least one current threshold value is adapted on the basis of the level of the current such that, in the case of an increasing current, the at least one current threshold value is reduced and that, in the case of a decreasing current, the at least one current threshold value is increased, in particular is increased up to a maximum value of the at least one current threshold value.

Advantageously, in the case of high currents, the current threshold value (the current threshold) is thus reduced, since, at high currents, there may be a high input of heat that is thus recognized better in order thus to make maximum use of the current-carrying capability or thermal capacity, in particular of the electronic interruption unit, more specifically of its (power) semiconductor, and at the same time the (power) semiconductor of the electronic interruption unit is protected against thermal destruction.

In one advantageous embodiment of the invention, the circuit breaker device is designed such that the at least one current threshold value is continuously adapted. An adaptation that is performed faster than 10 s, 5 s, 1 s, 200 ms, 100 ms, 50 ms, 20 ms, 10 ms or faster than 1 ms may furthermore in particular also take place (all intermediate values are possible and disclosed).

This has the particular advantage of quickly carrying along the current threshold value in order thus to achieve a maximum degree of use of the electronic interruption unit, in particular its (power) semiconductor/semiconductor-based switching element, and a good economic degree of use is thus achieved.

In one advantageous embodiment of the invention, in which provision is made for a voltage sensor unit connected to the control unit, so as to ascertain the level of the voltage of the low-voltage circuit such that (analog) instantaneous voltage values are present, instantaneous current threshold values (in particular periodic ones) that are dependent on the (in particular periodic) temporal characteristic of the level of the voltage (in particular AC voltage), that is to say on the instantaneous voltage values, are present.

The instantaneous current values are compared (in particular in terms of phase) with the instantaneous current threshold values. In the event of the instantaneous current threshold value being exceeded (in particular in terms of absolute value), interruption of the low-voltage circuit is initiated.

This has the particular advantage that threshold values/current threshold values dependent on the periodicity of the voltage are present in order to achieve fast current flow avoidance (tripping), in particular by way of the electronic interruption unit. In the case of high currents, small current threshold values are used.

In one advantageous embodiment of the invention, the (periodic) instantaneous current threshold values have a minimum value that is greater than zero. This minimum value is in particular greater than 5, 10, 15 or 20% of the maximum value; more specifically, it is in the range of 5 to 20% of the maximum value, that is to say of the maximum current threshold value.

This has the particular advantage, in the case of small current threshold values or small voltages, of enabling safe and fast recognition of short-circuit currents and avoiding incorrect tripping.

In one advantageous embodiment of the invention, the low-voltage circuit has a temporally sinusoidal voltage characteristic (ideal case). The low-voltage circuit is in particular a low-voltage AC circuit. The instantaneous current threshold values likewise have a temporally (approximately) sinusoidal current characteristic, in particular in terms of absolute value. The zero-crossing or the region of the zero-crossing in particular has a minimum value (in terms of absolute value) that is greater than zero; this minimum value is in particular greater than 5%, 10%, 15% or 20% of the maximum value; particularly specifically this minimum value is in the range from 5 to 20% of the maximum value, that is to say of the maximum current threshold value. The temporal characteristics of voltage and current threshold values are synchronized in terms of phase such that the time of the amplitude (maximum value) of the voltage matches the time of the amplitude (maximum value) of the current threshold value.

This has the particular advantage of enabling simple recognition in the case of (in particular) sinusoidal voltage characteristics. This is particularly advantageous for low-voltage AC circuits.

In particular, the region of the zero-crossing of the voltage matches the region of the minimum value of the current threshold value.

In one advantageous embodiment of the invention, the circuit breaker device is designed such that provision is made for a grid synchronization unit. This ascertains at least one phase angle (φ(t)) of the voltage and, alternatively, the amplitude (U) of the voltage from supplied instantaneous voltage values. Provision is made for a threshold value unit that is connected to the grid synchronization unit such that instantaneous current threshold values are ascertained using the phase angle (φ(t)) of the voltage, the amplitude (U) of the voltage and a maximum limit value/threshold value for the current threshold value. The instantaneous current values are compared with the instantaneous current threshold values in terms of phase so as to ascertain initiation of avoidance of a current flow (interruption).

This has the particular advantage of a further simple implementation of the solution.

The analog first subunit has an analog (current) comparator to which the instantaneous (analog) current values and the instantaneous (analog) current threshold values are supplied, the latter from the second subunit. The current threshold values are provided in terms of phase by the second subunit in particular in accordance with the temporal characteristic of the voltage. This makes it possible to compare the (analog) instantaneous current values with the (analog) instantaneous current threshold values in relation to the phase of the temporal characteristic of the voltage. As a result of this, it is possible to initiate interruption of the low-voltage circuit in the event of the (instantaneous) current threshold values being exceeded.

Analog instantaneous current value is understood to mean for example an analog instantaneous current value that represents the level of the current through an equivalent, such as a voltage (voltage signal), wherein the level of the voltage represents the level of the current. By way of example, an analog instantaneous current value is an analog measured value of the current that is present as a voltage signal that represents the current characteristic as an equivalent.

Analog instantaneous current threshold value is understood to mean for example an analog instantaneous current threshold value that indicates the level of the current through an equivalent, such as a voltage (voltage signal), wherein the level of the voltage represents the level of the current. By way of example, the analog instantaneous current threshold value is an analog signal that is present as a voltage (signal) that represents the instantaneous current threshold value (characteristic) as an equivalent.

Advantageously, avoidance of the current flow is initiated primarily by the electronic interruption unit. In addition, or in the presence of further criteria, galvanic interruption may be initiated by the mechanical isolating contact system.

According to the invention, what is claimed is a corresponding method for a circuit breaker device for a low-voltage circuit having electronic (semiconductor-based) switching elements, having the same and further advantages.

In the method for protecting an electrical low-voltage circuit for a circuit breaker device:
a mechanical isolating contact unit is connected in series with an electronic interruption unit,
the mechanical isolating contact unit is able to be switched by opening contacts so as to avoid a current flow or closing the contacts to allow a current flow in the low-voltage circuit,
the electronic interruption unit is able to be switched by semiconductor-based switching elements to a high-resistance state of the switching elements so as to avoid a current flow or a low-resistance state of the switching elements so as to allow a current flow in the low-voltage circuit,
the level of the current in the low-voltage circuit is ascertained such that analog instantaneous current values are present, these being compared with at least one analog first current threshold value by an analog first comparator and, in the event of an exceedance, avoidance of a current flow in the low-voltage circuit is initiated, in particular by switching the electronic interruption unit to a high-resistance state,
wherein the at least one analog first current threshold value is provided by a microprocessor-controlled digital second subunit.

This has the particular advantage of enabling particularly fast recognition of overcurrents or short circuits.

In one advantageous embodiment, the at least one first current threshold value is computed digitally. The at least one current threshold value is in particular computed taking into consideration the level of a temperature of the circuit breaker device, the level of the voltage of the low-voltage circuit or/and the level of the instantaneous current value. The at least one current threshold value is in particular adapted depending on the level of the temperature or of the voltage or of the current such that, in the case of an increasing temperature or decreasing voltage or increasing current, the at least one current threshold value is reduced and, in the case of a decreasing temperature or increasing voltage or decreasing current, the at least one current threshold value is increased, in particular is increased up to a maximum value of the at least one current threshold value.

This has the particular advantage of achieving not only fast recognition but also taking into consideration parameters of the circuit breaker device or low-voltage circuit.

According to the invention, what is claimed is a corresponding computer program product. The computer program product comprises commands that, when the program is executed by a microcontroller (=microprocessor), prompt same to improve the safety and speed of such a circuit breaker device or to achieve higher safety in the electrical low-voltage circuit to be protected by the circuit breaker device, specifically such that fast recognition of the exceedance of a current threshold value is achieved and fast avoidance of an electric currently flow is performed by the electronic interruption unit. The microcontroller (=microprocessor) is part of the circuit breaker device, in particular of the control unit.

According to the invention, what is claimed is a corresponding computer-readable storage medium on which the computer program product is stored.

According to the invention, what is claimed is a corresponding data carrier signal that transmits the computer program product.

All embodiments, both in dependent form referring back to patent claim 1 or 12, and referring back only to individual features or combinations of features of patent claims, bring about an improvement in a circuit breaker device for fast and safe shutdown in the event of overcurrents and short circuits and avoids thermal destruction of the semiconductor-based switching elements that are used in the event of overcurrents and short circuits.

The described properties, features and advantages of this invention and the way in which these are achieved will become clearer and more clearly comprehensible in connection with the following description of the exemplary embodiments, which are explained in more detail in connection with the drawing.

Here, in the drawing:

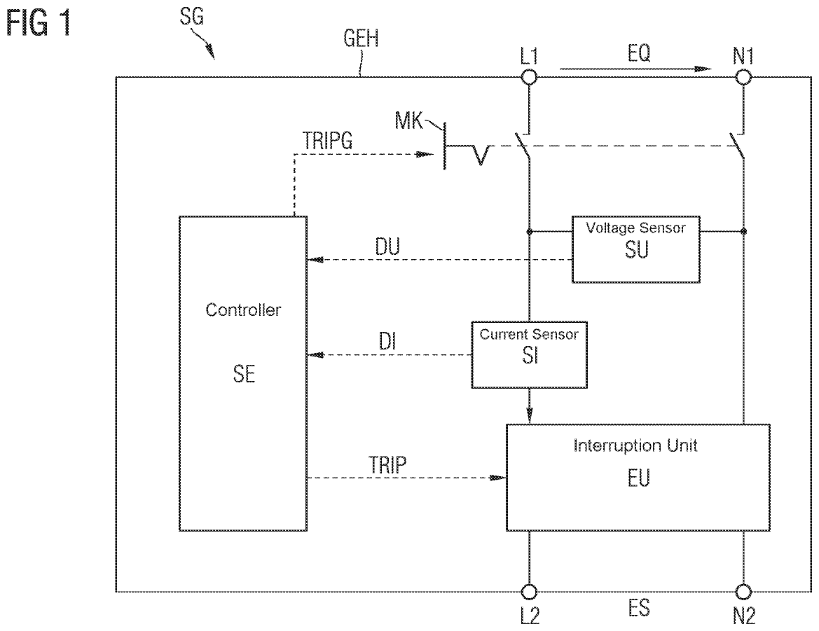

FIG. 1 shows a first illustration of a circuit breaker device,

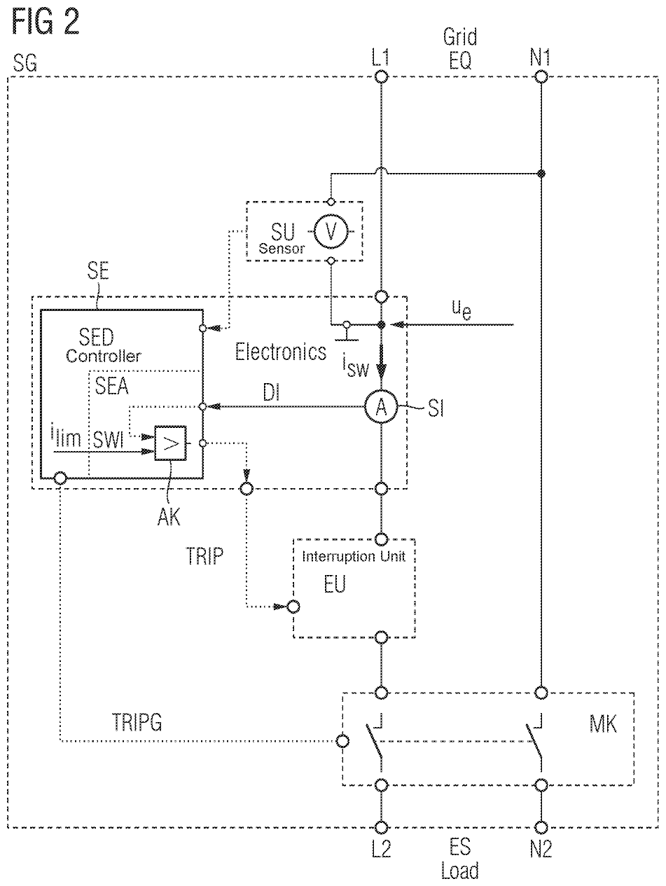

FIG. 2 shows a second illustration of a circuit breaker device,

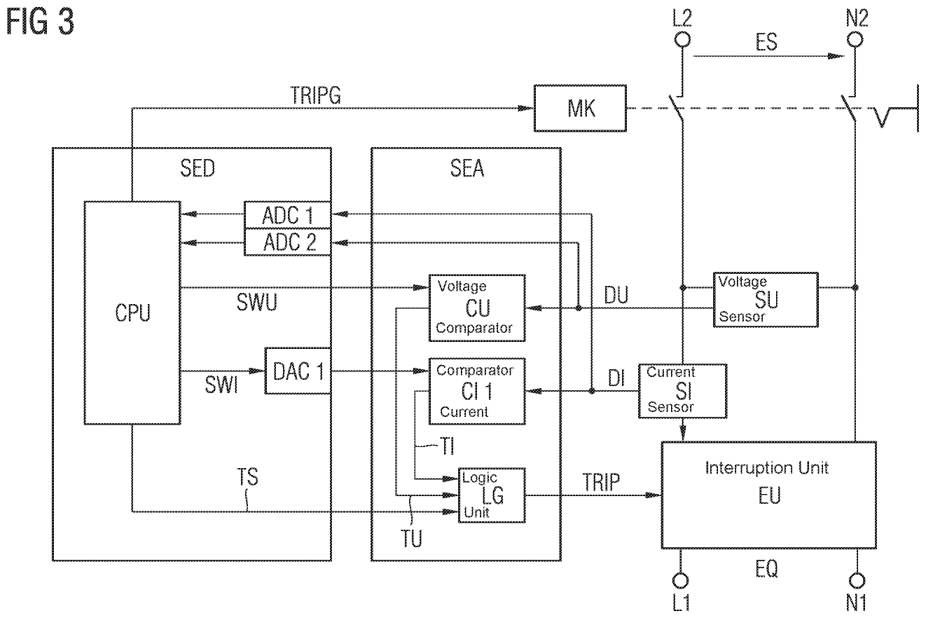

FIG. 3 shows a first embodiment of the circuit breaker device,

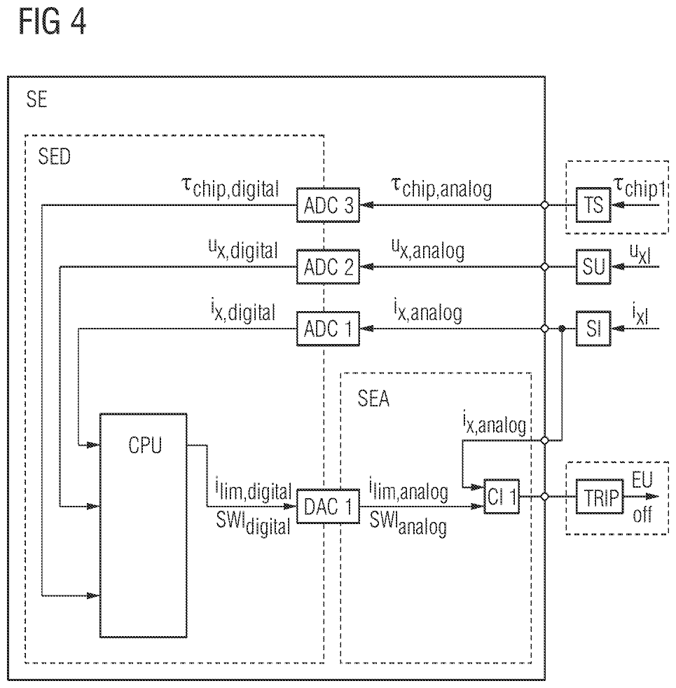

FIG. 4 shows a second embodiment of the circuit breaker device,

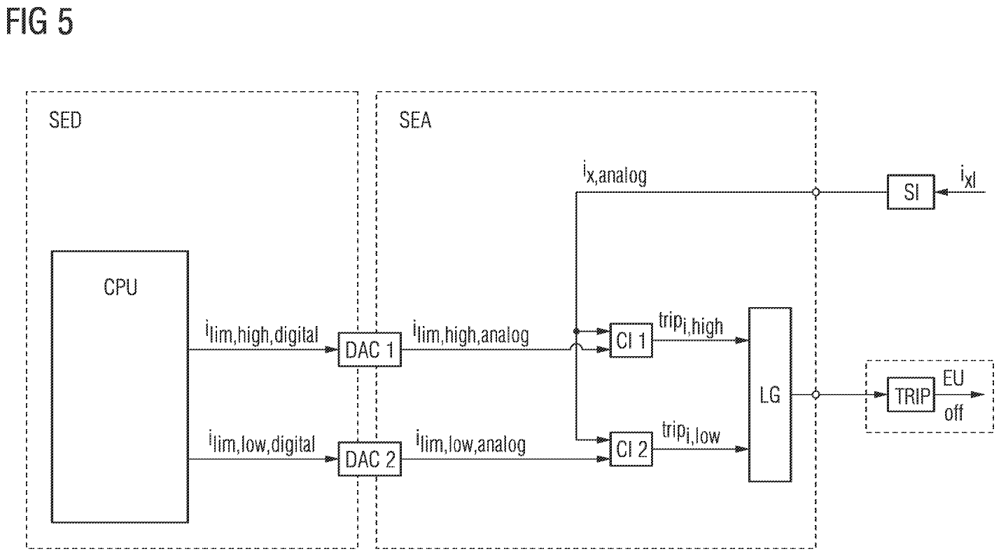

FIG. 5 shows a third embodiment of the circuit breaker device,

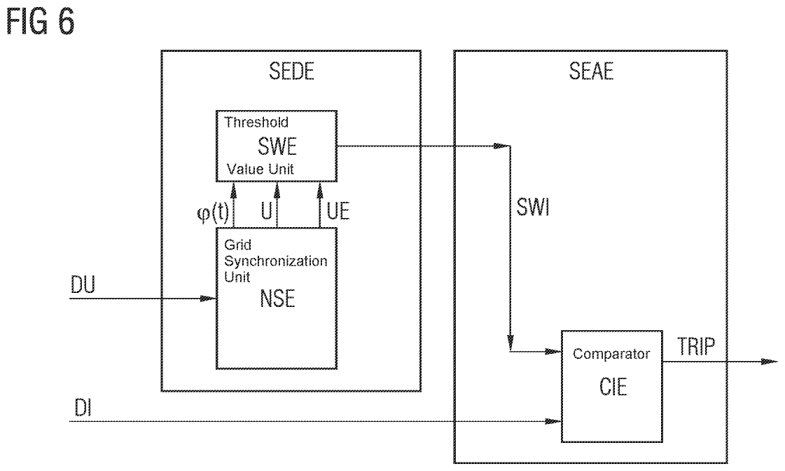

FIG. 6 shows a fourth embodiment of the circuit breaker device,

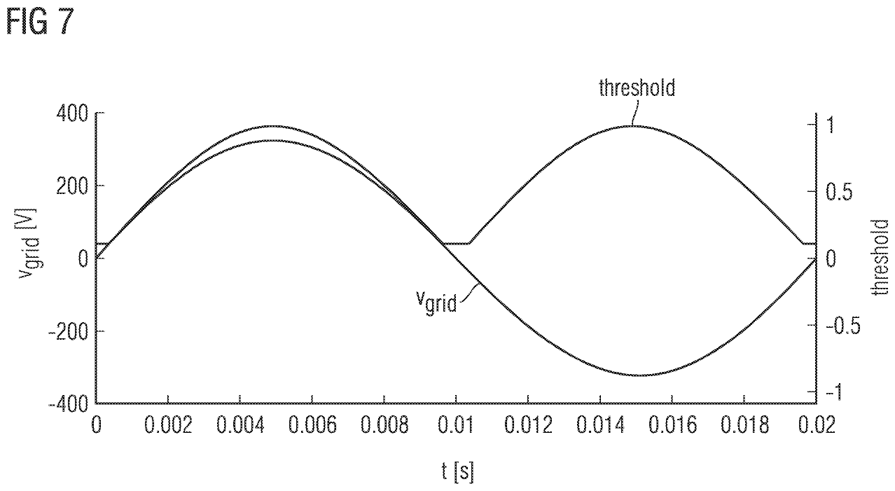

FIG. 7 shows voltage and current threshold value characteristics over time.

FIG. 1 shows an illustration of a circuit breaker device SG for protecting an electrical low-voltage circuit, in particular low-voltage AC circuit, having a housing GEH, having:
connections for conductors of the low-voltage circuit, in particular first connections L1, N1 for a grid-side, in particular energy source-side, connection EQ of the circuit breaker device SG and second connections L2, N2 for a load-side, in particular energy sink-side in the case of passive loads, connection ES (consumer-side connection) of the circuit breaker device SG, wherein provision may be made specifically for phase conductor-side connections L1, L2 and neutral conductor-side connections N1, N2;
the load-side connection may have a passive load (consumer) or/and an active load ((further) energy source), or a load, which may be both passive and active, for example in a time sequence;
a voltage sensor unit SU for ascertaining the level of the voltage of the low-voltage circuit such that instantaneous voltage values (phase-related voltage values) DU are present; instantaneous (phase angle-related) voltage values are understood to mean in particular analog instantaneous voltage values, that is to say for example an analog equivalent, that indicates the level of the voltage, for example an analog voltage, the level of which corresponds to that of the voltage,
a current sensor unit SI for ascertaining the level of the current of the low-voltage circuit such that instantaneous (phase angle-related) current values DI are present; instantaneous (phase angle-related) current values are understood to mean in particular analog instantaneous current values, that is to say for example an analog equivalent that indicates the level of the current, for example an analog voltage, the level of which corresponds to that of the electric current,
an electronic interruption unit EU that, by virtue of semiconductor-based switching elements, has a high-resistance state of the switching elements so as to avoid (in particular interrupt) and a low-resistance state of the switching elements so as to allow a current flow in the low-voltage circuit,
a mechanical isolating contact unit MK that is able to be switched by opening contacts so as to avoid a current flow or closing the contacts to allow a current flow in the low-voltage circuit,
a control unit SE that is connected to the voltage sensor unit SU, the current sensor unit SI, the mechanical isolating contact unit MK and the electronic interruption unit EU.

The mechanical isolating contact unit MK is electrically connected in series with the electronic interruption unit EU.

The control unit SE may:
be implemented with a digital circuit, for example with a microprocessor (=microcontroller); the microprocessor may also contain an analog part;
be implemented with a digital circuit having analog circuit parts.

The circuit breaker device SG, in particular the control unit SE, is designed such that, in the event of at least one current threshold value being exceeded, avoidance of a current flow in the low-voltage circuit is initiated, in particular is initiated in a first step by the electronic interruption unit EU.

In other words, in the event of at least one current threshold value being exceeded, this generally being caused by an in particular load-side (ES) short circuit, the electronic interruption unit EU is switched from the low-resistance state to the high-resistance state so as to interrupt the low-voltage circuit.

Provision may also be made for multiple current threshold values; provision may be made in particular for instantaneous/phase angle-related current threshold values, such that an instantaneous or phase angle-related comparison is performed depending on the phase angle of the voltage or of the electric current. These instantaneous or phase angle-related current threshold values may be adapted on the basis of the level of the current, of the voltage or/and of the temperature. Particularly in a low-voltage AC circuit, an adapted instantaneous or phase angle-related current threshold value may then be made available quickly, for example for the next half-cycle (or a set of adapted current threshold values for each half-cycle—adaptation every 10 ms in a low-voltage AC circuit with a grid frequency of 50 Hz).

A comparison may take place due to the fact that (in particular periodic) instantaneous current threshold values dependent on the (in particular periodic) temporal characteristic of the level of the voltage or the ascertained instantaneous voltage values are present.

The instantaneous current threshold values may be present continuously or phase angle-wise.

The instantaneous current threshold values may in this case be present per individual phase angle, a phase angle range (multiple phase angles), for example every 2°, or a phase angle section (part of a phase angle), for example every 0.5° or 0.1°. In particular, a resolution of 1° to 5° is particularly advantageous (this corresponds to a sampling rate of 3.5 to 20 kHz).

The instantaneous current values are compared to the instantaneous current threshold values in terms of phase. In the event of the instantaneous current threshold value being exceeded (in terms of absolute value) by the (absolute value of the) instantaneous current value, interruption of the low-voltage circuit is initiated, for example by a first interruption signal TRIP from the control unit SE to the electronic interruption unit EU, as illustrated in FIG. 1.

The electronic interruption unit EU is illustrated as a block in both conductors according to FIG. 1. In a first variant, this is understood to mean no interruption of the two conductors. At least one conductor, in particular the active conductor or phase conductor, has semiconductor-based switching elements. The neutral conductor may be free from switching elements, that is to say without semiconductor-based switching elements. In other words, the neutral conductor is connected directly, that is to say does not become highly resistive. In other words, only a single-pole interruption (of the phase conductor) takes place. If further active conductors/phase conductors are provided, in a second variant of the electronic interruption unit EU, the phase conductors have semiconductor-based switching elements. The neutral conductor is connected directly, that is to say does not become highly resistive. This is the case for example for a three-phase AC circuit.

In a third variant of the electronic interruption unit EU, the neutral conductor may likewise have a semiconductor-based switching element, that is to say, in the event of an interruption of the electronic interruption unit EU, both conductors become highly resistive.

The electronic interruption unit EU may have semiconductor components such as bipolar transistors, field-effect transistors (FETs), insulated-gate bipolar transistors (IGBTs), metal oxide-semiconductor field-effect transistors (MOSFETs) or other (self-commutated) power semiconductors. IGBTs and MOSFETs are particularly suitable for the circuit breaker device according to the invention due to low forward resistances, high blocking layer resistances and good switching behavior.

The circuit breaker device SG may preferably have a mechanical isolating contact system MK according to standards with standard-compliant isolator properties, in order to galvanically isolate the circuit, in particular in order to activate (in contrast to shut down) the circuit in a standard-compliant manner. The mechanical isolating contact system MK is connected to the control unit SE, as illustrated in FIG. 1, such that the control unit SE is able to initiate galvanic isolation of the circuit.

Specifically, a further evaluation may be implemented that brings about galvanic isolation when other criteria are met. By way of example, provision may be made for overcurrent recognition, for example in the control unit SE, such that, in the event of overcurrents, that is to say in the event of current time limit values being exceeded, that is to say when a current that exceeds a current limit value is present for a particular time, that is to say for example exceeds a particular energy threshold value, semiconductor-based or/and galvanic interruption of the circuit takes place.

As an alternative or in addition, galvanic isolation may also be initiated for example in the event of a recognized short circuit.

The galvanic interruption of the low-voltage circuit is initiated for example by a further second interruption signal TRIPG that is transmitted from the control unit SE to the mechanical isolating contact system MK, as illustrated in FIG. 1.

The mechanical isolating contact system MK may perform single-pole interruption in a first variant. In other words, only one conductor of the two conductors, in particular the active conductor or phase conductor, is interrupted, that is to say has a mechanical contact. The neutral conductor is then free from contacts, that is to say the neutral conductor is connected directly.

If further active conductors/phase conductors are provided, in a second variant, the phase conductors have mechanical contacts of the mechanical isolating contact system. In this second variant, the neutral conductor is connected directly. This is the case for example for a three-phase AC circuit.

In a third variant of the mechanical isolating contact system MK, the neutral conductor likewise has mechanical contacts, as illustrated in FIG. 1.

A mechanical isolating contact system MK is understood to mean in particular a (standard-compliant) isolating function, performed by the isolating contact system MK. Isolating function is understood to mean the following points:
minimum clearance in air according to standards (minimum distance between the contacts),
contact position indication for the contacts of the mechanical isolating contact system,
opening of the mechanical isolating contact system is always possible (no blocking of the isolating contact system caused by handling), so-called free tripping.

With regard to the minimum clearance in air between the contacts of the isolating contact system, this is essentially voltage-dependent. Other parameters are the pollution degree, the type of field (homogeneous, inhomogeneous) and air pressure or height above sea level.

There are corresponding rules or standards for these minimum clearances in air or creepage paths. These rules stipulate for example, in the case of air for a surge withstand capability, the minimum clearance in air for an inhomogeneous and a homogeneous (ideal) electric field on the basis of the pollution degree. The surge withstand capability is the withstand capability when a corresponding surge voltage is applied. The isolating contact system or circuit breaker device has an isolating function (isolator property) only in the presence of this minimum length (minimum clearance).

Within the scope of the invention, the DIN EN 60947 and IEC 60947 series of standards are relevant to the isolator function and the properties thereof in this case, to which standards reference is made here.

FIG. 2 shows an illustration according to FIG. 1, with the difference that advantageously (in the series circuit consisting of mechanical isolating contact unit MK and electronic interruption unit EU) the mechanical isolating contact unit MK is assigned to the load-side connections and the electronic interruption unit EU is assigned to the grid-side connections. The electronic interruption unit EU is furthermore designed as a single-pole electronic interruption unit EU, that is to say, in the example, is provided in the phase conductor, that is to say between the connections L1, L2. The electronic interruption unit EU furthermore has (at least) one semiconductor-based switching element (=power semiconductor), which is indicated in FIG. 2. The semiconductor-based switching element furthermore has an overvoltage protection element, which is likewise indicated in FIG. 2. The control unit SE has an analog first subunit SEA and a digital second subunit SED. The digital second subunit SED may for example be a microprocessor or digital signal processor (DSP). The analog first subunit SEA has at least one (current) comparator, as indicated in FIG. 2.

FIG. 3 shows an illustration according to FIGS. 1 and 2, having an embodiment according to the invention. The control unit SE has two subunits; an analog first subunit SEA and a digital second subunit SED. The first subunit SEA in this case has an analog first (current) comparator CI1. This is supplied with the analog instantaneous current values DI from the current sensor unit SI, on the one hand. On the other hand, the first current comparator CI1 is supplied with a current threshold value or (in a time sequence) instantaneous current threshold values SWI from the digital second subunit SED. A current comparator is understood here to mean a comparator that compares two (current) magnitudes with one another, wherein in this case in particular equivalents of the level of the current are compared with one another (for example two voltages whose voltage level represents in each case the current level or the level of the current threshold value).

The (analog) instantaneous current threshold values are in particular an analog voltage characteristic.

The analog first comparator CI1 compares the analog instantaneous current values DI with the analog instantaneous current threshold values SWI and outputs, as described, in the event of exceedance, a first current interruption signal TI so as to initiate interruption of the low-voltage circuit. The current interruption signal TI may be supplied to a logic unit LG, which combines it with other interruption signals and outputs the first interruption signal TRIP for semiconductor-based interruption or high-resistance interruption to the electronic interruption unit EU.

The analog first (current) comparator makes it possible in particular to achieve immediate, that is to say very quick, recognition of the exceedance; this usually takes place in the ns range, that is to say between 1 and 100 ns.

In comparison therewith, a digital system would react at present in the μs range, that is to say for example between 2-100 μs, due to the computing and reaction times.

In one embodiment, the first current comparator CI1 buffer stores the instantaneous (current) threshold values SWI in order to have the values constantly available.

The instantaneous current threshold values SWI are synchronized with the temporal characteristic of the instantaneous voltage values (the temporal characteristic of the voltage). As a result, for example in the case of a small instantaneous voltage (phase angle of a sinusoidal AC voltage of for example −30° to 0° to 30°, low instantaneous current threshold values SWI are used (or are present) and, in the case of a high instantaneous voltage (phase angle of a sinusoidal AC voltage of for example 60° to 90° to 120°, high current threshold values SWI are used (or are present). As a result, for example, the trip time is advantageously largely independent of the phase angle of the voltage, and so the trip time is below a temporal first threshold value.

The (analog) instantaneous current values DI and the (analog) instantaneous voltage values DU are additionally supplied to the second subunit SED. In one preferred embodiment, the instantaneous current values DI or/and instantaneous voltage values DU are digitized there by a first analog-to-digital converter ADC1 and supplied to a microprocessor (=microcontroller) CPU. This ascertains or computes the instantaneous current threshold values SWI, on the basis of the level of the current/of the supplied instantaneous current values DI. The instantaneous current threshold values SWI ascertained by the second subunit SED or in particular the microprocessor CPU are in turn supplied to the first subunit SEA by a first digital-to-analog converter DAC1, in particular to the first current comparator CI1, in order to perform the comparison described above.

The second subunit SED or the first subunit SEA may have the first digital-to-analog converter DAC1 in order to convert the (digital) current threshold values SWI computed in the second subunit SED into analog current threshold values SWI, in order to perform an analog comparison in the first analog subunit SEA. In the example according to FIG. 3, the first digital-to-analog converter DAC1 is part of the (digital) second subunit SED (or assigned thereto).

In this case, the instantaneous current threshold values SWI may advantageously be ascertained digitally in the second subunit SED or with a slower processing speed than the continuous comparison of analog instantaneous current values DI with the analog instantaneous current threshold values SWI in the first subunit SEA. This is advantageous as the analog comparison of the current value takes place more quickly than the processing time or computing time of the digital second subunit SED.

The phase-accurate comparison is generally ensured by the fast processing speeds of the first analog-to-digital converter ADC1, microprocessor (=microcontroller) CPU and first digital-to-analog converter DAC1 in comparison with the frequency of the low-voltage circuit, which is generally 50 hertz in Europe.

In one advantageous embodiment of the invention, the first subunit SEA may have a voltage comparator CPU, as illustrated in FIG. 3. This is supplied with the instantaneous voltage values DU of the voltage sensor SU, on the one hand. On the other hand, the voltage comparator CU is supplied with instantaneous voltage threshold values SWU by the second subunit SED.

The voltage comparator CU compares the instantaneous voltage values DU with the instantaneous voltage threshold values SWU and, in the event of exceedance or undershoot or a range check, outputs a voltage interruption signal TU so as to initiate interruption of the low-voltage circuit.

The voltage interruption signal TU may be supplied to the logic unit LG, which combines it with the one or more other interruption signals and outputs the first interruption signal TRIP for the semiconductor-based interruption or high-resistance interruption to the electronic interruption unit EU.

In one embodiment, the voltage comparator CU buffer stores the instantaneous threshold values SWU in order to have the values constantly available.

In one embodiment, the microprocessor CPU ascertains or computes the instantaneous voltage threshold values SWU. The instantaneous voltage threshold values SWU ascertained by the second subunit SED or in particular the microprocessor CPU are supplied in turn to the first subunit SEA, in particular to the voltage comparator CU, in order to perform the comparison described above. The digital instantaneous voltage threshold values SWU may be converted into analog instantaneous voltage threshold values SWU by a further digital-to-analog converter, not illustrated. These instantaneous voltage threshold values are compared with the analog instantaneous voltage values DU by the voltage comparator CU.

In this case, the instantaneous voltage threshold values SWU may advantageously be ascertained digitally in the second subunit SED or at a slower processing speed than the continuous comparison of instantaneous voltage values DU and instantaneous voltage threshold values SWU in the first subunit SEA.

Depending on the embodiment, a second interruption signal TRIPG may be output by the second subunit SED of the control unit SE, in particular by the microprocessor CPU, to the mechanical isolating contact system MK so as to galvanically interrupt the low-voltage circuit, as illustrated in FIG. 3.

The embodiment of the control unit with an analog first subunit and a digital second subunit has the particular advantage that an efficient architecture is present. The first analog subunit is able to perform a very fast comparison of instantaneous values and threshold values, thereby enabling fast short-circuit recognition. The second subunit may perform a threshold value computation or adaptation that is independent thereof, according to the invention depending on the level of the current, that does not have to be performed as quickly as the recognition. The threshold values may for example be buffer stored in order to be available for a fast comparison. The threshold values do not have to be adapted constantly.

FIG. 4 shows an illustration according to FIG. 3, with the difference that provision is made for a temperature sensor unit TS, which is connected to the control unit SE, in particular to the second subunit SED, for ascertaining the level of at least one temperature τ_{,chip} in the circuit breaker device, in particular for ascertaining at least one temperature of a unit of the circuit breaker device, in particular at least one temperature of the electronic interruption unit (EU), specifically of at least one semiconductor-based switching element, such that (analog) instantaneous temperature values τ_{,chip,analog} are present. The analog instantaneous temperature values τ_{,chip,analog} are digitized into digital instantaneous temperature values τ_{,chip,digital} by a third analog-to-digital converter ADC3. They may thus be processed by the microprocessor CPU of the second subunit SED and in particular influence the level of the one or more current threshold values.

Provision is furthermore made for a second analog-to-digital converter ADC2, similarly to FIG. 3, which digitizes the analog instantaneous voltage values DU or u_{x,analog} analog into digital instantaneous voltage values u_{x,digital}, such that they are able to be processed by the second subunit SED and may for example influence the level of the one or more current threshold values.

FIG. 5 shows a further illustration according to FIGS. 3 and 4, with the difference that provision is made for an analog first comparator CI1 and an analog second comparator CI2. The second comparator CI2 corresponds to the first comparator CI1. Provision is furthermore made for a second digital-to-analog converter DAC2. The second digital-to-analog converter DAC2 corresponds to the first digital-to-analog converter DAC1.

At least one digital first current threshold value i_{lim,high,digital} is supplied to the first digital-to-analog converter DAC1 and at least one digital second current threshold value i_{lim,low,digital} is supplied to the second digital-to-analog converter DAC2, which convert said values into at least one analog first current threshold value i_{lim,high,analog} and at least one analog second current threshold value i_{lim,low,analog} and supply them to the first and second comparator CI1, CI2, respectively. The outputs of the first and second comparator CI1, CI2 are logically or-linked via the logic unit LG and possibly further signals.

The analog first comparator CI1 (continuously) compares the analog instantaneous current value DI or i_{x,analog} with the at least one analog first current threshold value i_{lim,high,analog} and, in the event of an exceedance, outputs a first signal trip_{,high} for avoiding the current flow in the low-voltage circuit at its output, to the logic unit LG. The analog second comparator (continuously) compares the analog instantaneous current value DI or i_{x,analog} with the at least one analog second current threshold value i_{lim,low,analog} and, in the event of an undershoot, outputs a second signal trip_{,low} for avoiding the current flow in the low-voltage circuit at its output, to the logic unit LG. If an exceedance or undershoot is present, the low-voltage circuit is interrupted (off), in particular by way of the electronic interruption unit EU.

FIG. 6 shows a further embodiment or variant according to FIGS. 1 to 5. FIG. 6 shows part of a simple variant of the preferably analog first subunit SEAE and part of an alternative variant of the preferably digital second subunit SEDE.

The part of the simple variant of the first subunit SEAE has the (current) comparator CIE, to which the analog instantaneous current values DI, in particular for example their absolute value, and the analog instantaneous current threshold values SWI, in particular also in terms of absolute value, are supplied. The analog (current) comparator CIE in this example directly outputs the first interruption signal TRIP so as to interrupt the low-voltage circuit, in the same way as the previous figures. The absolute value may be computed by one or further units that are not illustrated.

The part of the alternative variant of the second subunit SEDE has a grid synchronization unit NSE. This is supplied with the (analog) instantaneous voltage values DU. The grid synchronization unit NSE ascertains, from the supplied (analog) instantaneous voltage values DU, which are for example a sinusoidal AC voltage of the low-voltage circuit, the phase angle φ(t) of the voltage.

As an alternative, the amplitude U and an expected temporal value of the voltage UE or expected value of the voltage UE may also additionally be ascertained.

The expected value of the voltage UE is in this case a type of filtered or regenerated or generated equivalent instantaneous voltage value DU.

The phase angle φ(t) (and also the expected value of the voltage UE or the amplitude U) of the voltage DU may for example be ascertained by a so-called phase-locked loop or PLL for short. A PLL is an electronic circuit arrangement or a software-programmed variant in the microcontroller that influences the phase and thus accordingly the frequency of a changeable oscillator via a closed control loop such that the phase difference between an external periodic reference signal (instantaneous voltage values) and the oscillator or a signal derived therefrom is as constant as possible.

This makes it possible to ascertain inter alia the phase angle φ(t), the fundamental frequency and the amplitude thereof of the supplied grid voltage, that is to say the ascertained voltage values, that is to say for example also the (untouched or filtered) expected value of the (grid) voltage.

The phase angle φ(t) ascertained by the grid synchronization unit NSE (and possibly the amplitude U or/and the expected temporal value of the voltage UE) are supplied to a threshold value unit SWE. The threshold value unit SWE may have a (scaled) curve for the (phase-related) instantaneous current threshold values SWI. By way of example, in the case of a sinusoidal AC voltage of the low-voltage circuit, an (approximately) sinusoidal current threshold value curve, that is to say a characteristic that is sinusoidal in terms of height of the instantaneous current threshold values SWI over the phase angles 0° to 360° or the period duration (or the (corresponding) time).

The circuit breaker device SG may have a, in particular a single, setting element. This in particular single setting element on the circuit breaker device SG makes it possible to set a limit value or maximum value for the current threshold value. As an alternative, the limit value or maximum value for the current threshold value may also be fixedly prescribed or programmed.

According to the invention, the current threshold value curve is then scaled with regard to this limit value or maximum value for the current threshold value as set or fixedly prescribed by way of the setting element. By way of example, the amplitude (that is to say the maximum value) of the current threshold value curve may be scaled with the limit value/maximum value for the current threshold value.

By way of example, the maximum value of the current threshold value may be 4 times the amplitude of a nominal current (that is to say at least the current that has to be carried at all times by the circuit breaker device, depending on the standard) of the circuit breaker device; for example, normal circuit breaker devices have a nominal current of for example 16 A. In the example, this results in a maximum value of the current threshold value of:

90 A=(root 2)*16 A*4.

(root 2=>amplitude of the nominal current value)

The instantaneous current threshold values SWI, owing to the presence of the phase angle φ(t) of the voltage in the threshold value unit SWE, may be transmitted thereby, synchronously with the instantaneous current value DI, to the current comparator CIE, such that a phase-related (phase angle-related) comparison between the instantaneous current value DI and the instantaneous current threshold value SWI may take place.

FIG. 7 shows, on the one hand, the characteristic of the level of a grid-side voltage Vgrid in volts [V], on the left-hand vertical axis, of a period of a sinusoidal AC voltage over time t in s [s], on the horizontal axis, for example of a sinusoidal AC voltage in the low-voltage AC circuit. In this case, the instantaneous voltage values of the voltage are indicated over time, with time being proportional to the phase angle (f=50 Hz).

On the other hand, said figure shows a phase angle-related or phase angle-dependent (absolute value) scaled (0 to 1) instantaneous current threshold value threshold, on the right-hand vertical axis, over time t in s [s]. The temporal (scaled) characteristic of the instantaneous current threshold values threshold in this case corresponds to the (phase angle-related) instantaneous current threshold values SWI.

The temporal characteristic of the instantaneous current threshold value (threshold) is governed here by the absolute value characteristic of the voltage, that is to say the characteristic, in the region of the positive voltage half-cycle, is the same as the characteristic in the region of the negative voltage half-cycle.

The temporal (scaled) characteristic of the instantaneous current threshold values threshold is scaled in accordance with the limit value/maximum value for the current threshold value according to the invention as set or fixedly prescribed by way of the setting element. For example, the amplitude (scaling 1) is set to 100 A, or for example 5 times the nominal current. In the case of a nominal current of for example 16 A, to for example

5*16A*1.414(root 2)=113A

(root 2=>peak value of the instantaneous value of the current).

Generally speaking, the characteristic of the instantaneous current threshold values threshold corresponds to the characteristic of the voltage in the circuit, as illustrated in FIG. 7. In other words, for example in the case of a triangular voltage characteristic, a triangular current threshold value curve would be used. The background is that the level of the voltage defines the level of the (short-circuit) current. According to the invention, in the case of a high current, low threshold values are therefore used and, in the case of a low current, high threshold values are used in order to enable fast, phase angle-independent short circuit recognition.

According to FIG. 7, the (periodic) instantaneous current threshold values SWI have a minimum value. In other words, the sinusoidal curve is not ideal (only roughly or approximately sinusoidal). The minimum value is greater than zero. The minimum value is in particular greater than 5%, 10%, 15% or 20% of the maximum value. More specifically, this minimum value may be in the range of 5 to 20% of the maximum value, for example (at) 10% or 15%, that is to say the amplitude of the current threshold value curve threshold. The minimum value occurs at the location or in the region of the zero-crossing of the (sinusoidal) curve for the current threshold values.

In the case of a temporally sinusoidal voltage characteristic in the low-voltage AC circuit, the temporal characteristics of voltage and current threshold values are synchronized in terms of phase such that the time of the amplitude (maximum value) of the voltage matches the time of the amplitude (maximum value) of the current threshold value, as shown in FIG. 7. The region of the zero-crossing of the voltage also matches the region of the minimum value of the current threshold value.

The phase angle resolution defines the speed of the computing of the threshold values. With a phase angle resolution of 1°, that is to say a threshold value is present for each full phase angle of the voltage, that is to say an instantaneous threshold value is present roughly every 55.5 μs. The shutdown is preferably performed by an analog comparator, that is to say continuously, and is thus significantly faster (for example in the nanosecond range) than the phase angle resolution.

As an alternative, the following temporal characteristic applies in the case of fully digital processing. The phase angle resolution defines the speed of the recognition. With a phase angle resolution of 1°, that is to say a threshold value is present for each full phase angle of the voltage, that is to say an instantaneous threshold value is present roughly every 55.5 μs, this means that shutdown is able to take place after a minimum of around 60 μs. It is possible to achieve shorter shutdown times with higher phase angle resolutions.

In this example, the values are then processed at at least 18 kHz.

The current threshold values may also be stored (in scaled form) in a table, with the value then possibly being adapted.

Although the invention has been described and illustrated in more detail by the exemplary embodiment, the invention is not restricted by the disclosed examples and other variations may be derived therefrom by a person skilled in the art without departing from the scope of the invention.

1-16. (canceled)

17. A circuit breaker device for protecting an electrical low-voltage circuit, the circuit breaker comprising:
a housing having first and second connections for conductors of the electrical low-voltage circuit;
a series circuit of a mechanical isolating contact unit and an electronic interruption unit, said series circuit electrically connects said first and said second connections, wherein said mechanical isolating contact unit has contacts and is able to be switched by opening said contacts so as to avoid a current flow or closing said contacts to allow the current flow in the electrical low-voltage circuit, wherein said electronic interruption unit has semiconductor-based switching elements and is able to be switched by said semiconductor-based switching elements to a high-resistance state of said semiconductor-based switching elements so as to avoid the current flow or a low-resistance state of said semiconductor-based switching elements so as to allow the current flow in the electrical low-voltage circuit;
a current sensor for ascertaining a level of a current of the electrical low-voltage circuit, such that analog instantaneous current values are present; and
a controller connected to said current sensor, said mechanical isolating contact unit and said electronic interruption unit, wherein said controller has a microprocessor-controlled digital second subunit that provides at least one digital first current threshold value, said controller has an analog first subunit with an analog first comparator that is connected to said current sensor, said analog first subunit being further connected to said microprocessor-controlled digital second subunit, said controller further has a first digital-to-analog converter that converts the at least one digital first current threshold value into at least one analog first current threshold value, wherein said analog first comparator compares an analog instantaneous current value with the at least one analog first current threshold value and, in an event of an exceedance of the at least one analog first current threshold value, said analog first comparator outputs a signal for avoiding the current flow in the electrical low-voltage circuit at an output of said analog first comparator.

18. The circuit breaker device according to claim 17, wherein in the event of the analog instantaneous current value exceeding the at least one analog first current threshold value, avoidance of the current flow in the electrical low-voltage circuit is initiated.

19. The circuit breaker device according to claim 17,
wherein said analog first subunit has said analog first comparator and an analog second comparator that are both connected to said current sensor, said current sensor provides the analog instantaneous current value for both said analog first comparator and said analog second comparator, and said analog first and second comparators are further coupled to said microprocessor-controlled digital second subunit;
wherein said microprocessor-controlled digital second subunit provides the at least one digital first current threshold value for said analog first comparator and at least one digital second current threshold value for said analog second comparator;
wherein said controller has a second digital-to-analog converter that converts the at least one digital second current threshold value into at least one analog second current threshold value, and said analog first comparator compares the analog instantaneous current value with the at least one analog first current threshold value and, in an event of an exceedance, said analog first comparator outputs a signal for avoiding the current flow in the electrical low-voltage circuit at said output of said analog first comparator; and
wherein said analog second comparator compares the analog instantaneous current value with the at least one analog second current threshold value and, in an event of an undershoot, said analog second comparator outputs a signal for avoiding the current flow in the electrical low-voltage circuit at an output of said analog second comparator.

20. The circuit breaker device according to claim 19, wherein:
in the event of the analog instantaneous current value exceeding the at least one analog first current threshold value, avoidance of the current flow in the electrical low-voltage circuit is initiated;
in the event of the analog instantaneous current value falling below the at least one analog second current threshold value, avoidance of the current flow in the electrical low-voltage circuit is initiated; and
in both cases, the electronic interruption unit switches to the high-resistance state.

21. The circuit breaker device according to claim 19, further comprising a voltage sensor connected to said controller so as to ascertain a level of a voltage of the electrical low-voltage circuit such that instantaneous voltage values are present.

22. The circuit breaker device according to claim 19, further comprising a temperature sensor unit connected to said controller for ascertaining a level of at least one temperature in the circuit breaker device such that instantaneous temperature values are present.

23. The circuit breaker device according to claim 22, wherein:
said microprocessor-controlled digital second subunit is configured such that the at least one first or/and second current threshold value is computed digitally; and
the at least one current threshold value is adapted depending on the level of the at least one temperature or of the voltage or of the current such that, in a case of an increasing temperature or a decreasing voltage or an increasing current, the at least one current threshold value is reduced and, in a case of a decreasing temperature or an increasing voltage or a decreasing current, the at least one current threshold value is increased.

24. The circuit breaker device according to claim 21, wherein:
the at least one analog first current threshold value is one of a plurality of analog instantaneous current threshold values that are dependent on periodic temporal characteristic of the instantaneous voltage values that are present; and
the analog instantaneous current values are compared, in terms of phase, with the analog instantaneous current threshold values by way of a least one said analog first and second comparators and in that, in an event of the instantaneous first and/or second current threshold value being exceeded/fallen below, interruption of the electrical low-voltage circuit is initiated.

25. The circuit breaker device according to claim 21, wherein:
the electrical low-voltage circuit has a temporally sinusoidal voltage characteristic;
instantaneous current threshold values including the at least one analog first and second current threshold values have a temporally approximately sinusoidal current threshold value characteristic; and
temporal characteristics of the voltage and the instantaneous current threshold values are synchronized in terms of phase such that a time of an amplitude of the voltage matches a time of an amplitude of the current threshold value.

26. The circuit breaker device according to claim 25, wherein a region of a zero-crossing of the voltage matches a region of a minimum value of the current threshold value.

27. The circuit breaker device according to claim 17, wherein:
said first connections are grid-side connections and said second connections are load-side connections; and
said mechanical isolating contact unit is assigned to said load-side connections and said electronic interruption unit is assigned to said grid-side connections.

28. The circuit breaker device according to claim 18, wherein in the event of the analog instantaneous current value exceeding the at least one analog first current threshold value, avoidance of the current flow in the electrical low-voltage circuit is initiated by said electronic interruption unit switching to the high-resistance state.

29. The circuit breaker device according to claim 21, wherein said voltage sensor unit is connected to said microprocessor-controlled digital second subunit of said controller.

30. The circuit breaker device according to claim 22, wherein said temperature sensor unit is connected to said microprocessor-controlled digital second subunit of said controller for ascertaining at least one temperature of said electronic interruption unit.

31. The circuit breaker device according to claim 23, wherein:
the first and/or the second current threshold value is computed taking into consideration the level of the temperature, the level of the voltage or the level of the instantaneous current value; and
in the case of the decreasing temperature or the increasing voltage or the decreasing current, the at least one current threshold value is increased up to a maximum value of the at least one current threshold value.

32. A method for protecting an electrical low-voltage circuit for a circuit breaker device, the circuit breaker having a mechanical isolating contact unit connected in series with an electronic interruption unit, which comprises the steps of:
switching contacts of the mechanical isolating contact unit to an open state so as to prevent a current flow or to a closed state to allow the current flow in the electrical low-voltage circuit;
switching semiconductor-based switching elements of the electronic interruption unit to a high-resistance state so as to avoid the current flow or to a low-resistance state so as to allow the current flow in the electrical low-voltage circuit;
ascertaining a level of a current in the electrical low-voltage circuit such that analog instantaneous current values are present;
comparing the analog instantaneous current values with at least one analog first current threshold value via an analog first comparator and, in an event of an exceedance, avoidance of the current flow in the electrical low-voltage circuit is initiated, by switching the electronic interruption unit to the high-resistance state; and
providing the at least one analog first current threshold value from a microprocessor-controlled digital second subunit.

33. The method according to claim 32, wherein:
the at least one first current threshold value is computed digitally, wherein the at least one first current threshold value is computed taking into consideration a level of a temperature of the circuit breaker device, a level of a voltage of the electrical low-voltage circuit or a level of an instantaneous current value; or
the at least one first current threshold value is adapted depending on a level of the temperature or of the voltage or of the current such that, in a case of an increasing temperature or a decreasing voltage or an increasing current, the at least one first current threshold value is reduced and, in a case of a decreasing temperature or an increasing voltage or a decreasing current, the at least one first current threshold value is increased.

34. A non-transitory computer program, comprising computer executable instructions that when executed by a processor carry out the method according to claim 32.

35. A non-transitory computer-readable storage medium storing the computer program according to claim 34.
